(19) United States
(12) Patent Application Publication
(10) Pub. No.: US 2025/0043905 A1
(43) Pub. Date: Feb. 6, 2025

(54) ATTACHMENT MECHANISM

(71) Applicant: Acer Incorporated, New Taipei City (TW)

(72) Inventors: Ching-Yi Lu, New Taipei City (TW); Ching-Yu Tien, New Taipei City (TW); Yu-Liang Chiu, New Taipei City (TW)

(73) Assignee: Acer Incorporated, New Taipei City (TW)

(21) Appl. No.: 18/743,084

(22) Filed: Jun. 13, 2024

(30) Foreign Application Priority Data
Aug. 1, 2023 (TW) 112128872

(51) Int. Cl. F16M 13/02; H05K 5/02; H05K 5/03

(52) U.S. Cl. CPC F16M 13/02; H05K 5/0204; H05K 5/03

(57) ABSTRACT

An attachment mechanism for attaching a first electronic device and a second electronic device together is provided. The attachment mechanism includes a connecting base and an attachment block. The connecting base is assembled on the second electronic device, and the connecting base includes a body and a door, wherein the body has a receiving slot, and the door is movably assembled on the body to shield a portion of the receiving slot or expose the receiving slot. The attachment block is assembled on the first electronic device. When the receiving slot is exposed, the attachment block is inserted and locked in the receiving slot, and the door shields the portion of the receiving slot to stop the attachment block, so that the first electronic device is attached to the second electronic device via the attachment block and the body.

### CROSS-REFERENCE TO RELATED APPLICATION

This application claims the priority benefit of Taiwan application serial no. 112128872, filed on Aug. 1, 2023. The entirety of the above-mentioned patent application is hereby incorporated by reference herein and made a part of this specification.

### BACKGROUND OF THE INVENTION

### Field of the Invention

The invention relates to an attachment mechanism.

### Description of Related Art

Nowadays, some monitors may be used in a suspended manner, usually by locking to a rack and hanging on a wall or ceiling, for example, and there are VESA standard lock holes on both the back of the display and between the hangers, so as to achieve a unified screw lock specification. Furthermore, with the miniaturization and diversification of computer systems, computer hosts disposed on the back of the display, such as mini PCs, are further derived to enrich the application range of the display.

At present, the above applications are only limited to installing or mounting the host computer on the back of the monitor, and there is no additional usage mode. Furthermore, the user still assembles all members by means of locking, so there is still quite complicated and inconvenient assembling succession.

### SUMMARY OF THE INVENTION

The invention provides an attachment mechanism providing a simple structure capable of quick disassembly and multi-dimensional movement, so as to improve the convenience of disassembly and expand the application modes after assembly.

An attachment mechanism of the invention is for attaching a first electronic device and a second electronic device together. The attachment mechanism includes a connecting base and an attachment block. The connecting base is assembled on the second electronic device, and the connecting base includes a body and a door, wherein the body has a receiving slot, and the door is movably assembled on the body to shield a portion of the receiving slot or expose the receiving slot. The attachment block is assembled on the first electronic device. When the receiving slot is exposed, the attachment block is inserted and locked in the receiving slot, and the door shields the portion of the receiving slot to stop the attachment block, so that the first electronic device is attached to the second electronic device via the attachment block and the body.

Based on the above, the attachment mechanism is assembled on the attachment block of the first electronic device and the connecting base of the second electronic device, and the connecting base receives and locks the attachment block via the receiving slot thereof, then the attachment block is simply and rapidly stopped and held via the movable door, so that the attachment block may be fixed on the connecting base, so as to finish the structural assembly between the first electronic device, the attachment block, the connecting base, and the second electronic device. This simple structure may provide the effect of rapid disassembly and assembly between the first electronic device and the second electronic device, and effectively simplifies the existing complicated assembly process of locking one by one via screws.

### BRIEF DESCRIPTION OF THE DRAWINGS

FIG. 1 is a schematic view of the use of an attachment mechanism according to an embodiment of the invention.

FIG. 2 and FIG. 3 are respectively schematic diagrams showing the assembly of the attachment mechanism in FIG. 1.

FIG. 4 is an exploded view of a connecting base of an attachment mechanism.

FIG. 5 shows an exploded view of FIG. 4 from another perspective.

FIG. 6A and FIG. 6B are partial schematic diagrams of a connecting base from a front view.

FIG. 7A and FIG. 7B are partial schematic diagrams of a connecting base from a side view.

### DESCRIPTION OF THE EMBODIMENTS

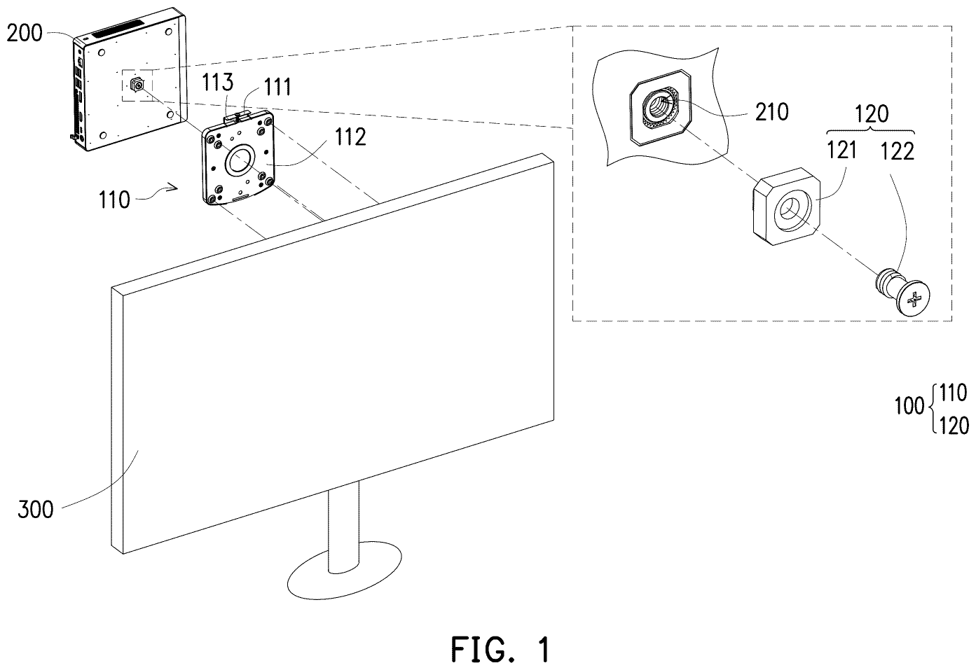

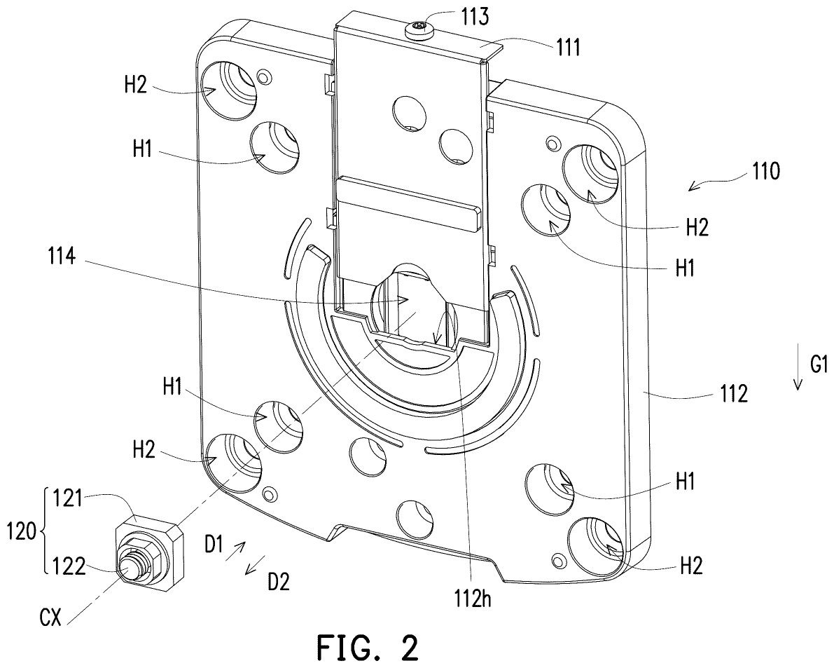

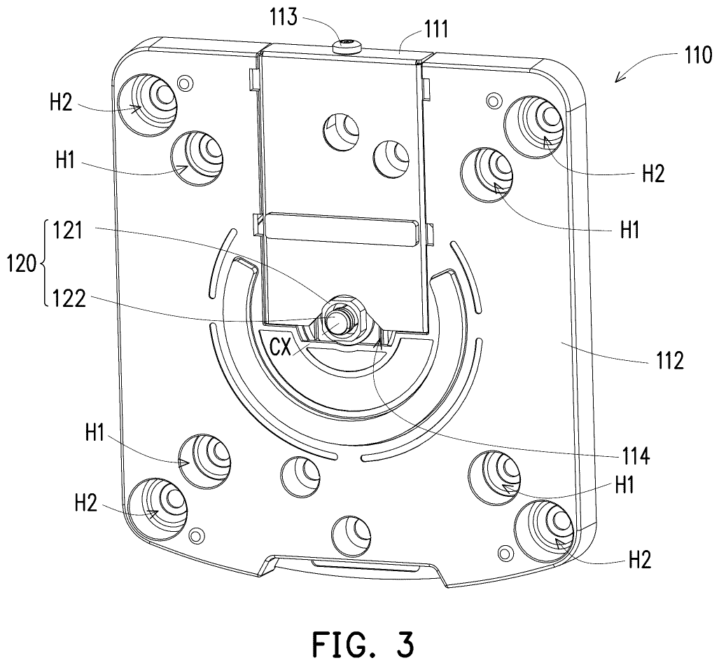

FIG. 1 is a schematic view of the use of an attachment mechanism according to an embodiment of the invention. FIG. 2 and FIG. 3 are respectively schematic diagrams showing the assembly of the attachment mechanism in FIG. 1. Please refer to FIG. 1 to FIG. 3 at the same time. In the present embodiment, an attachment mechanism 100 is used to attach a first electronic device 200 and a second electronic device 300 together. Here, the first electronic device 200 is a computer host (such as mini PC), and the second electronic device 300 is a display. The attachment mechanism 100 includes a connecting base 110 and an attachment block 120. The connecting base 110 is assembled on the second electronic device 300, and the attachment block 120 is assembled on the first electronic device 200. The computer host is assembled on the back of the display via the attachment block 120 and the connecting base 110.

As shown in FIG. 2 and FIG. 3, the attachment block 120 includes a block body 121 and a screw 122, wherein the screw 122 passes through the block body 121 and is locked to a screw hole 210 of the first electronic device 200. The connecting base 110 includes a body 112 and a door 111, wherein the body 112 has a plurality of locking holes H1 and H2 conforming to the VESA mount interface standard to lock the body 112 to the back of the display via screws (not shown). Moreover, the body 112 has a receiving slot 114, and the door 111 is movably assembled on the body 112 to shield a portion of the receiving slot 114 or expose the receiving slot 114. When the receiving slot 114 is exposed, the attachment block 120 is inserted and locked in the receiving slot 114, and drives the door 111 to shield the portion of the receiving slot 114 to stop the attachment block 120, so that the first electronic device 200 is attached to the second electronic device 300 via the attachment block 120 and the body 112.

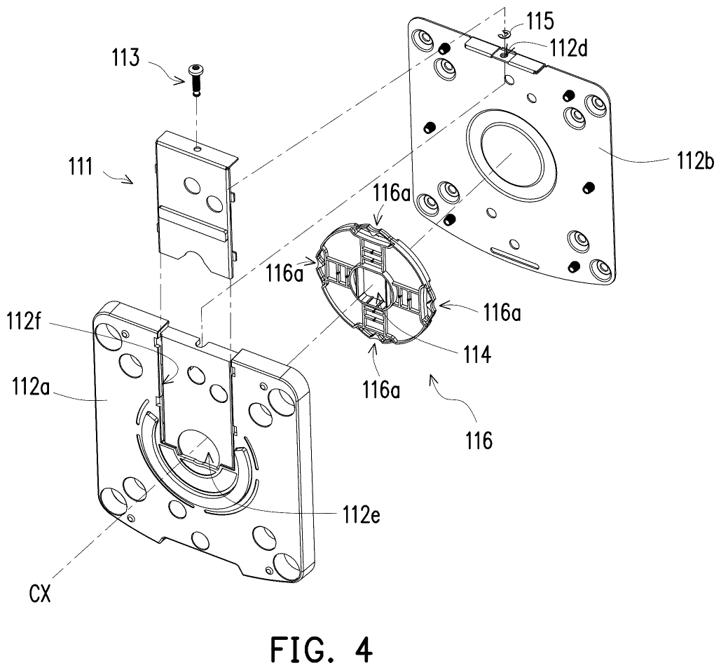

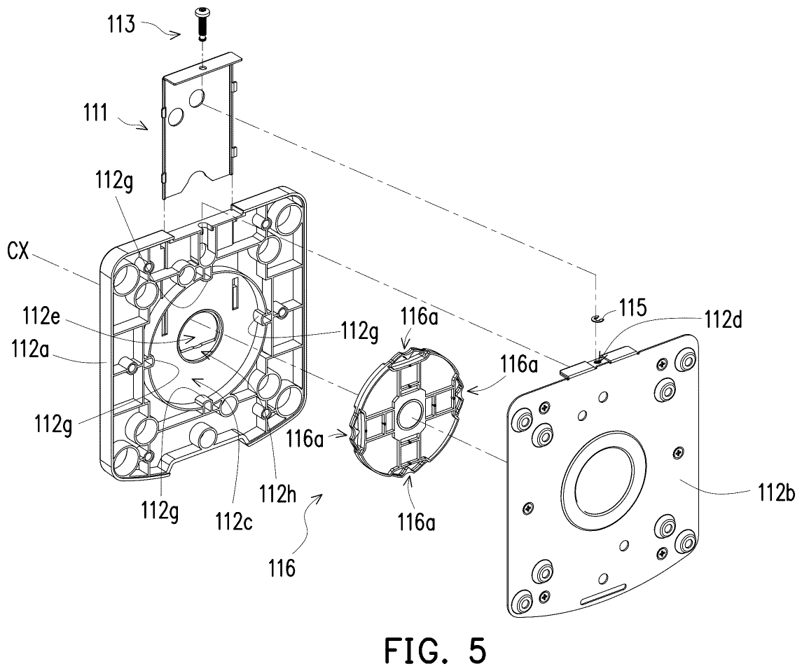

FIG. 4 is an exploded view of a connecting base of an attachment mechanism. FIG. 5 shows an exploded view of FIG. 4 from another perspective. Please refer to FIG. 4 and FIG. 5 at the same time. In the present embodiment, the body 112 includes a first shell 112a and a second shell 112b attached to each other. In the assembled first electronic device 200, attachment mechanism 100, and second electronic device 300, the first shell 112a is located between the first electronic device 200 and second shell 112b, the second shell 112b is located between the first shell 112a and the second electronic device 300, the first shell 112a has an opening 112e and a chute 112f, and the door 111 is movably coupled to the chute 112f to expose the opening 112e or shield a portion of the opening 112e. Accordingly, when the user assembles the attachment block 120 on the first electronic device 200 and drives the door 111 away to expose the opening 112e, the attachment block 120 on the first electronic device 200 may be driven to be inserted into the receiving slot 114 along a direction D1, as shown in FIG. 2. Next, the user drives the door 111 to reset, and as shown in FIG. 3, the fallen door 111 becomes a portion of the structure preventing the attachment block 120 from moving out of the receiving slot 114 along a direction D2. The direction D1 is opposite to the direction D2.

Further, as shown in FIG. 4 and FIG. 5, in the attachment mechanism 100 of the present embodiment, the connecting base 110 further includes a turntable 116 rotatably disposed in the body 112 along a rotation axis CX. Here, the first shell 112a has a carrying slot 112c, and the turntable 116 is rotatably assembled on the carrying slot 112c. The opening 112e is located at the center of the carrying slot 112c, the chute 112f and the carrying slot 112c are located at two opposite surfaces of the first shell 112a, and the rotating shaft CX passes through the opening 112e. More importantly, the turntable 116 has the receiving slot 114, and when the turntable 116 is assembled on the carrying slot 112c, the receiving slot 114 and the first shell 112a further form a sinking slot 112h adjacent to the opening 112e. In this way, when the attachment block 120 is inserted into the receiving slot 114 along the first direction D1, the first electronic device 200 and the attachment block 120 may be moved via a gravity G1, so that a portion of the attachment block 120 is extended into the sinking slot 112h, so that the first shell 112a stops the attachment block 120 from moving out of the receiving slot 114 along the second direction D2. Accordingly, since when the door 111 falls along the direction of the gravity G1 to shield the portion of the receiving slot 114, the door 111 and the sinking slot 112h are opposite to each other, the door 111 and the first shell 112a are respectively stopped at the upper portion and the lower portion of the attachment block 120, wherein the upper portion and the lower portion are arranged along the direction of the gravity G1.

Moreover, the attachment block 120 and the receiving slot 114 of the present embodiment are a polygonal body and a polygonal slot for which the contours are adapted to each other, the attachment block 120 is a quadrangular board, and the receiving slot 114 is a quadrangular slot. Therefore, the receiving slot 114 may provide the effect of confining and locking the attachment block 120. Conversely, the first electronic device 200 may also be inserted and locked in the receiving slot 114 via the attachment block 120 to drive the turntable 116 to rotate along the rotation axis CX in the body 112. In this way, after the first electronic device 200, the attachment mechanism 100, and the second electronic device 300 are assembled, the user may drive the first electronic device 200 to rotate relative to the second electronic device 300 along the rotation axis CX, so as to generate a corresponding position and a corresponding state meeting usage requirements by adjusting the relative positions of the first electronic device 200 and the second electronic device 300.

Moreover, please refer to FIG. 4 and FIG. 5 again, the carrying slot 112c of the present embodiment is a circular slot adapted to the turntable 116, the periphery of the carrying slot 112c has a plurality of positioning protrusions 112g, and the periphery of the turntable 116 has a plurality of positioning notches 116a, so that during the rotation process of the turntable 116, the positioning protrusions 112g are temporarily sunk into the positioning notches 116a to provide the positioning of the rotation stroke of the turntable 116. The number of the positioning protrusions 112g and the positioning notches 116a is not limited here, but in another unillustrated embodiment, the positioning protrusions 112g may also be disposed at the turntable 116, and the positioning notches 116a may be disposed at the carrying slot 112c.

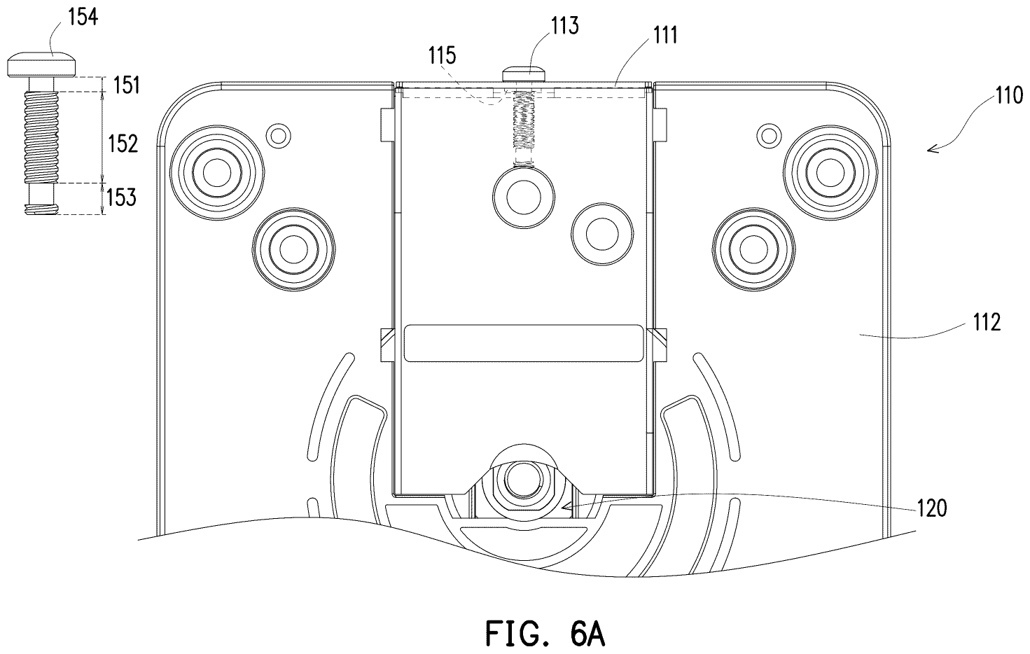

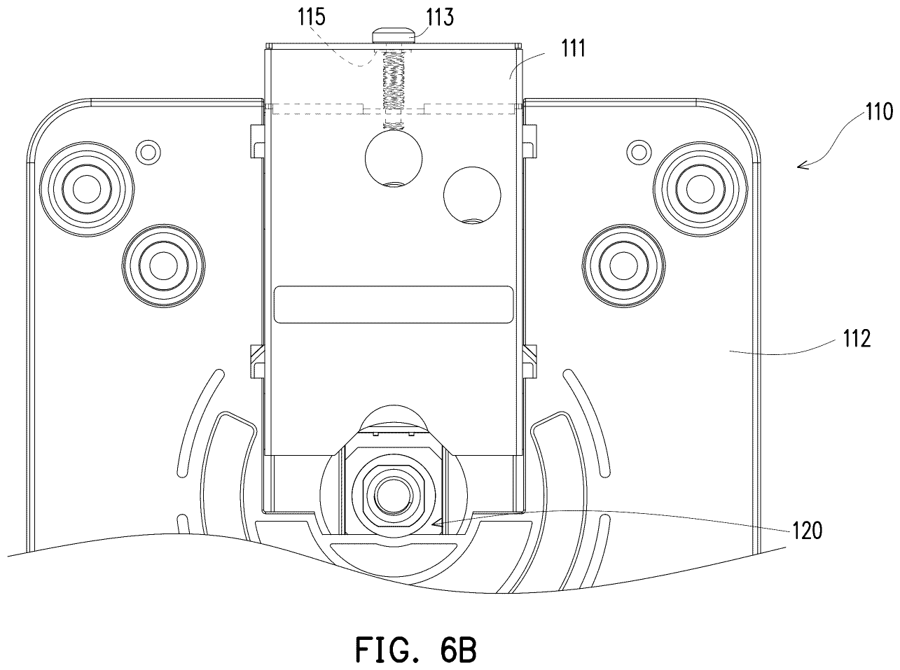

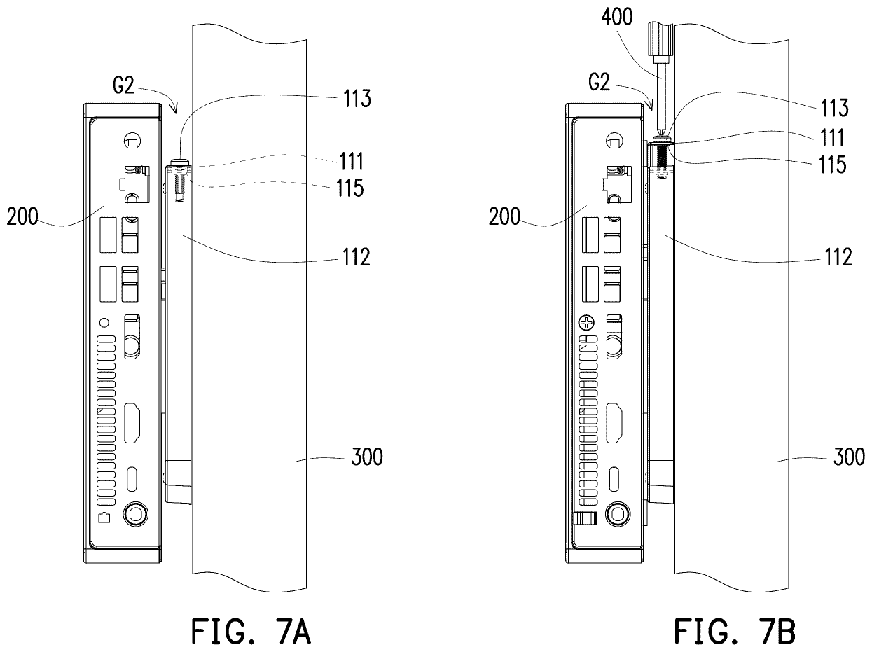

FIG. 6A and FIG. 6B show partial schematic diagrams of a connecting base from a front view, wherein FIG. 6A shows the closed state of the door 111, and FIG. 6B shows the open state of the door 111. FIG. 7A and FIG. 7B show partial schematic diagrams of a connecting base from a side view, wherein FIG. 7A corresponds to FIG. 6A, and FIG. 7B corresponds to FIG. 6B. Please first refer to FIG. 6A and FIG. 7A and compare FIG. 4 or FIG. 5. In the present embodiment, the attachment mechanism 100 also includes a screw 113 and a fastener 115, the screw 113 is pivotally assembled on the door 111 via the fastener 115, and is used for locking to the body 112 or unlocking from the body 112, and during the unlocking process, the door 111 is pushed away from the body 112 via the screw 113.

Further, as shown in FIG. 6A, the screw 113 includes a head 154 and a screw rod, and the screw is further divided into a first section 151, a second section 152, and a third section 153, wherein the first section 151 is connected between the head 154 and the second section 152, the second section 152 is connected between the first section 151 and the third section 153, the second section 152 has threads, and the first section 151 and the third section 153 do not have threads. Moreover, the fastener 115 is fastened to the first section 151 to clamp a portion of the door 111 between the head 154 and the fastener 115 to achieve the structural relationship between the screw 113 and the door 111 which is pivotable but has no relative displacement.

Correspondingly, please refer to FIG. 4, FIG. 6A, and FIG. 6B at the same time, or refer to FIG. 4, FIG. 7A, and FIG. 7B at the same time, the body 112 of the present embodiment also has a screw hole 112d located at the second shell 112b for screwing or unlocking with the second section 152 of the screw 113. During the unlocking process, with the help of the relative force exerted by the screw thread of the second section 152 and the internal thread of the screw hole 112d, as the screw 113 is gradually risen (transition process from FIG. 6A to FIG. 6B), the head 154 is gradually moved away from the body 112, the second section 152 gradually passes through the screw hole 112d, and because of the corresponding structural relationship between the screw 113 and the door 111, the withdrawal movement of the screw 113 from the body 112 may drive the door 111 to gradually move away from the receiving slot 114 to open the opening 112e.

As shown in FIG. 7A and FIG. 7B, since the first electronic device 200 is attached to the back of the second electronic device 300 via the attachment mechanism 100, a gap G2 is obviously formed between the two, and considering the volume after assembly and the convenience of operation, the gap G2 may only be disassembled by inserting a screwdriver 400. But in this way, on the premise that the user's hands cannot be inserted into the gap G2, screw locking at the gap G2 becomes a troublesome and difficult process. There is also the difficulty of not being able to remove the screw, putting the screw in, or even dropping the screw (for example, falling into the gap G2).

Based on the above issues, the present embodiment may solve the above issues smoothly via the screw 113 shown in FIG. 6A and attaching the screw 113 to the door 111 via the fastener 115 so as to be pivotable but without relative displacement. As shown in FIG. 6A, for the screw 113, the first section 151 and the third section 153 of the screw rod have no threads, and only the second section 152 has threads. Therefore, in the process of driving the screw 113 to exit the body 112 via the screwdriver 400, when the user finds that the screw 113 is idling, the third section 153 at this time has entered the screw hole 112d of the body 112, as shown in FIG. 6B, the screw 113 has lifted the door 111 to open the opening 112e to expose the receiving slot 114. Therefore, the user may smoothly withdraw the attachment block 120 from the receiving slot 114 to remove the first electronic device 200 from the connecting base 110. Conversely, this is also an assembling opportunity for inserting the attachment block 120 into the receiving slot 114. It should be mentioned that even if the user removes the screwdriver 400 at this time, the screw 113 and the door 111 are also kept in the state shown in FIG. 6B or FIG. 7B because the threads of the second section 152 and the threads of the screw hole 112d are abutted against each other. In this way, whether the screw 113 is in the locked state or the unlocked state, the screw 113 may be maintained on the body 112 of the connecting base 110. Therefore, the attachment mechanism 100 of the present embodiment does not have issues such as removing the screw 113 and the door 111, and further provides convenience for the user in the process of disassembling and assembling the first electronic device 200.

Based on the above, in an embodiment of the invention, the attachment mechanism is assembled on the attachment block of the first electronic device and the connecting base of the second electronic device, and the connecting base receives and locks the attachment block via the receiving slot thereof, then the attachment block is simply and rapidly stopped and held via the movable door, so that the attachment block may be fixed on the connecting base, so as to finish the structural assembly between the first electronic device, the attachment block, the connecting base, and the second electronic device. This simple structure may provide the effect of rapid disassembly and assembly between the first electronic device and the second electronic device, and effectively simplifies the existing complicated assembly process of locking one by one via screws.

Moreover, the attachment mechanism is also provided with a turntable in the connecting base, and the turntable has the receiving slot receiving the attachment block, and the user may drive the first electronic device to rotate relative to the second electronic device by locking the attachment block in the receiving slot.

Moreover, via the structural relationship between the screw, the fastener, and the door, the screw is pivotable but attached to the door without relative displacement, so that the user may also drive the door to exit the receiving slot during the process of withdrawing the screw. At the same time, the screw rod also has different sections with threads and without threads, so the user may know whether the door has exited the receiving slot by detecting whether the screw is idling. And more importantly, the attachment mechanism does not need to disassemble and assemble screws in an unfavorable environment, thereby bringing convenience to the user during the disassembly and assembly process.

What is claimed is:

1. An attachment mechanism, for attaching a first electronic device and a second electronic device together, the attachment mechanism comprising:
a connecting base assembled on the second electronic device, the connecting base comprising:
a body having a receiving slot;
a door movably assembled on the body to shield a portion of the receiving slot or expose the receiving slot; and
an attachment block assembled on the first electronic device, wherein when the receiving slot is exposed, the attachment block is inserted and locked in the receiving slot, and the door shields the portion of the receiving slot to stop the attachment block, so that the first electronic device is attached to the second electronic device via the attachment block and the connecting base.

2. The attachment mechanism of claim 1, wherein the connecting base further comprises a turntable rotatably disposed in the body along a rotating shaft, the turntable has the receiving slot, and the first electronic device is inserted and locked in the receiving slot via the attachment block, and drives the turntable to rotate in the body.

3. The attachment mechanism of claim 2, wherein the body comprises a first shell and a second shell attached to each other, the first shell is located between the first electronic device and the second shell, the second shell is located between the first shell and the second electronic device, the first shell has a door and a chute, and the door is movably coupled to the chute to expose the door or shield a portion of the door.

4. The attachment mechanism of claim 3, wherein the rotating shaft passes through the door.

5. The attachment mechanism of claim 3, wherein the first shell has a carrying slot, the turntable is rotatably assembled on the carrying slot, the door is located at a center of the carrying slot, and the chute and the carrying slot are located at two opposite surfaces of the first shell.

6. The attachment mechanism of claim 5, wherein when the turntable is assembled on the carrying slot, the receiving slot and the first shell form a sinking slot adjacent to the door.

7. The attachment mechanism of claim 6, wherein after the attachment block is inserted into the receiving slot along a first direction, the attachment block is partially sunk into the sinking slot via a gravity, so that the first shell stops the attachment block from moving out of the receiving slot along a second direction, and the first direction and the second direction are opposite to each other.

8. The attachment mechanism of claim 7, wherein when a portion of the attachment block sinks into the sinking slot and the door shields the portion of the receiving slot, the door and the sinking slot are opposite to each other, the door and the first shell are stopped at an upper portion and a lower portion of the attachment block, and the upper portion and the lower portion are arranged along a direction of the gravity.

9. The attachment mechanism of claim 5, wherein the carrying slot is a circular slot adapted to the turntable, a periphery of the carrying slot has a plurality of positioning protrusions or a plurality of positioning notches, and a periphery of the turntable has a plurality of positioning notches or positioning protrusions, so that a positioning of a rotation stroke of the turntable is provided by the positioning protrusions temporarily falling into the positioning notches.

10. The attachment mechanism of claim 1, further comprising a screw assembled on the door and locked to the body or unlocked from the body, wherein during the unlocking process, the door is pushed away from the body via the screw.

11. The attachment mechanism of claim 10, wherein the screw comprises a head and a screw rod, and the screw rod has a first section, a second section, and a third section, the first section is connected between the head and the second section, the second section is connected between the first section and the third section, the second section has threads, and the first section and the third section do not have threads.

12. The attachment mechanism of claim 11, further comprising a fastener buckled on the first section, so that a portion of the door is clamped between the head of the screw and the fastener, so that the screw and the door are pivotally connected together.

13. The attachment mechanism of claim 12, wherein the body has a screw hole for locking or unlocking with the second section of the screw, and during the unlocking process, the head of the screw is gradually moved away from the body to drive the door to gradually move away from the receiving slot.

14. The attachment mechanism of claim 1, wherein the attachment block and the receiving slot are a polygonal body and a polygonal slot for which contours are adapted to each other.

15. The attachment mechanism of claim 1, wherein the body has a plurality of locking holes conforming to a VESA mount interface standard.

16. The attachment mechanism of claim 1, wherein the first electronic device is a computer host, the second electronic device is a display, and the computer host is assembled on a back of the display via the attachment block and the connecting base.
